(19) United States
(12) Patent Application Publication
(10) Pub. No.: US 2014/0110246 A1
(43) Pub. Date: Apr. 24, 2014

(54) METHODS FOR DEPOSITING A HOMOGENEOUS FILM VIA SPUTTERING FROM AN INHOMOGENEOUS TARGET

(71) Applicant: PRIMESTAR SOLAR, INC., Arvada, CO (US)

(72) Inventors: Scott Daniel Feldman-Peabody, Golden, CO (US); Robert Dwayne Gossman, Aurora, CO (US); Mark Jeffrey Pavol, Arvada, CO (US)

(73) Assignee: PRIMESTAR SOLAR, INC., Arvada, CO (US)

(21) Appl. No.: 13/654,461

(22) Filed: Oct. 18, 2012

(51) Int. Cl. C23C 14/35; C23C 14/08; C23C 14/14

(52) U.S. Cl. 204/192.15; 204/192.12

(57) ABSTRACT

Methods for forming a thin film layer on a substrate are provided. The method can include: rotating a cylindrical target about a center axis; ejecting atoms from the sputtering surface with a plasma; transporting a substrate across the plasma at a substantially consistent speed; and depositing the atoms ejected from the sputtering surface onto the substrate to form a thin film layer. The cylindrical target generally includes a source material forming a sputtering surface about the cylindrical target, with the source material having a plurality of first areas and a plurality of second areas. Each first area includes a first compound, and each second area includes a second compound, while the first compound is different than the second compound.

### FIELD OF THE INVENTION

The subject matter disclosed herein relates generally the use of inhomogeneous semiconducting targets during deposition of a substantially homogeneous thin film layer on a substrate.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials.

The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., an electron accepting layer) and the CdS layer acts as a n-type layer (i.e., an electron donating layer). Free carrier pairs are created by light energy and then separated by the p-n heterojunction to produce an electrical current.

The CdS layer, along with other layers (e.g., a transparent conductive oxide layer such as a cadmium tin oxide layer) can be formed via a sputtering process (also know as physical vapor deposition) where the source material is supplied from a semiconducting target. The target utilized to deposit such a layer is typically formed from a ceramic material (e.g., cadmium sulfide, cadmium tin oxide, etc.) and/or a metal material (e.g., pressed cadmium and tin) and present in the sputtering surface as a substantially homogeneous composition. As such, the substantially homogeneous target can be sputtered to form a substantially homogeneous thin film layer.

However, making a homogeneous sputtering target of a mixed compound can be very expensive and adds significant cost per watt to the resulting photovoltaic module manufactured. For example, cadmium (Cd) and tin (Sn) are not miscible materials, so the two metals must be pressed together in an expensive process.

As such, a need exists for methods forming a substantially uniform thin film layer from a sputtering target that may have very large domains of different and separate materials (i.e., an inhomogeneous sputtering target) in order to reduce the cost of the target, resulting in a lower cost per watt of the photovoltaic module.

### BRIEF DESCRIPTION OF THE INVENTION

Aspects and advantages of the invention will be set forth in part in the following description, or may be obvious from the description, or may be learned through practice of the invention.

Methods are generally provided for forming a thin film layer on a substrate. In one embodiment, the method can include: rotating a cylindrical target about a center axis; ejecting atoms from the sputtering surface with a plasma; transporting a substrate across the plasma at a substantially consistent speed; and depositing the atoms ejected from the sputtering surface onto the substrate to form a thin film layer. The cylindrical target generally includes a source material forming a sputtering surface about the cylindrical target, with the source material having a plurality of first areas and a plurality of second areas. Each first area includes a first compound, and each second area includes a second compound, while the first compound is different than the second compound.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a perspective view of an exemplary cylindrical sputtering target including a source material of alternating first areas and second areas forming a sputtering surface;

FIG. 2 shows a side view of one embodiment of the exemplary cylindrical sputtering target of FIG. 1;

FIG. 3 shows a side view of another embodiment of the exemplary cylindrical sputtering target of FIG. 1;

FIG. 4 shows a side view of yet another embodiment of the exemplary cylindrical sputtering target of FIG. 1;

FIG. 5 shows a side view of still another embodiment of the exemplary cylindrical sputtering target of FIG. 1;;

FIG. 6 shows a perspective view of another exemplary cylindrical sputtering target including a source material of dispersed first areas and second areas forming a sputtering surface;

FIG. 7 shows a close-up view of one portion of the sputtering surface of the exemplary cylindrical sputtering target of FIG. 6; and,

FIG. 8 shows an exemplary sputtering chamber for use with any of the cylindrical sputtering targets of FIGS. 1-7.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

A method is generally provided for sputtering an inhomogeneous cylindrical target, along with the sputtering targets and their methods of formation. In use, the cylindrical target is rotated quickly to ensure that the inhomogeneities in the cylindrical target are blurred over very small sections of the deposited thin film layer (e.g., within a monolayer of the thin film layer). As such, a substantially homogeneous thin film layer can be deposited on a substrate via sputtering of the inhomogeneous cylindrical target. When utilized in the formation of a thin film layer of a photovoltaic module, the cost per watt of the resulting module can be significantly lowered through this sputtering process.

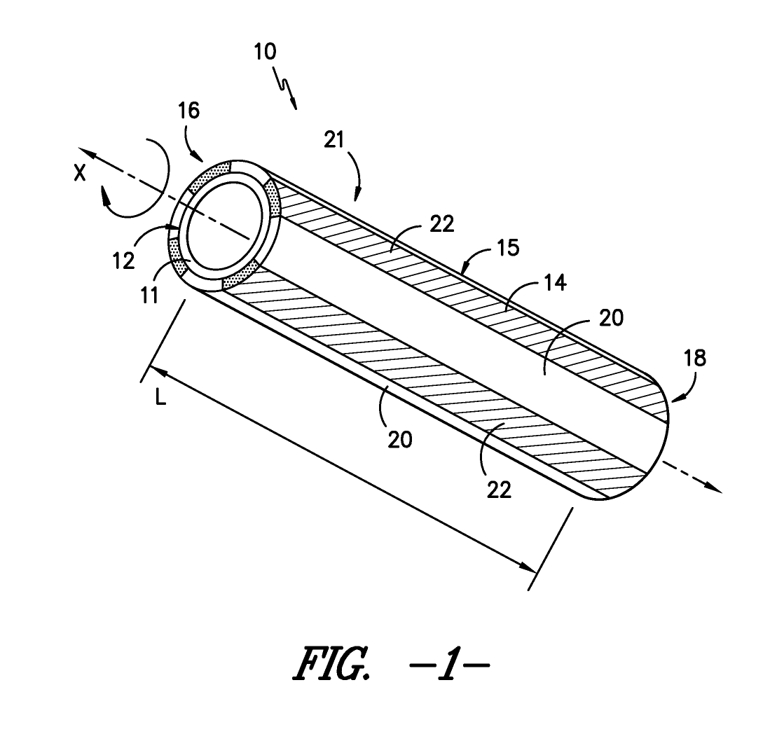

FIGS. 1 and 6 show exemplary embodiments of cylindrical targets 10 that have a tubular member 11 defining tube surface 12. The tubular member 11 has a length (L) in a longitudinal direction, and an inner radius R_{I} from a center axis (X) oriented in the longitudinal direction of the cylindrical target 10. Though shown as having a generally cylindrical shape (e.g., a drum having a generally circular in its cross-section), the tubular member 11 can be formed into any suitable rotatable shape. For example, the tubular member 11 can have a polygon-like cross-section. The tubular member 11 is shown having a hollow cylinder-like configuration. However, it is to be understood that internal elements may be included within the construction of the tubular member 11, such as support structures (e.g., spokes), magnets, cooling devices, etc.

A source material 14 is positioned about the tube surface 12 to form a sputtering surface 15 about the cylindrical target 10. The cylindrical target 10 has an outer radius (R_{O}) defined from the center axis (X) to the sputtering surface 15. As shown, the source material 14 defines a substantially continuous sputtering surface 15 about the circumference of the cylindrical target 10 and across the length (L) of the cylindrical target 10. Thus, the cylindrical target 10 can be sputtered with a reduction, or substantial elimination, of nodules formed in the target's sputtering surface 15. As such, the outer radius (R_{O}) can remain substantially uniform across the length of the cylindrical target 10 during sputtering.

The source material 14 can be bonded or non-bonded to the tube surface 12 of the tubular member 11. As used herein the term “bonded” refers to the source material 14 attached to the tube surface 12 (e.g., via welding, a solder, an adhesive, or other attachment material present between the source material 14 and the tubular member 11). Alternatively, the term “non-bonded” refers to the source material 14 being free from any attachment material to the tube surface 12 (i.e., no welding, solder, adhesive, or other attachment material is present between the source material 14 and the tubular member 11).

The source material 14 generally comprises a plurality of first areas 20 and a plurality of second areas 22. Each first 20 area includes a first compound, and each second 22 area includes a second compound that is different than the first compound. In one embodiment, the first compound and the second compound are not miscible materials.

For example, the first compound can be cadmium (Cd), and the second compound can be tin (Sn). In one particular embodiment, the total composition of the source material 14 can include cadmium and tin in a stoichiometric ratio between about 2 to 1 and about 10 to 1 (e.g., between about 2 to 1 and about 6 to 1). Additionally, in certain embodiments, at least one of the first compounds or the second compound includes oxygen (e.g., CdO, SnO, etc.).

As shown in FIGS. 1-5, the first area 20 and the second area 22 form alternating strips in the sputtering surface 15. The alternating strips are substantially oriented in the longitudinal direction and span from a first end 16 of the cylindrical target 10 to a second end 18 of the cylindrical target 10.

In certain embodiments, the alternating strips 21 are keyed together such that one first area 20 is mechanically interlocked with an adjacent second area 22. As such, the sputtering surface 15 can be substantially continuous throughout the sputtering process. For example, each first area 20 can define a male member 30 on one side and a female member 32 on an opposite side. Likewise, each second area 22 can define a substantially identical male member 30 and a substantially identical female member 32. The first areas 20 and the second areas 22 can be arranged such that the male member 30 of each first area interlocks with a female member 32 of an adjacent second area 22, while the male member 30 of each second area interlocks with a female member 32 of an adjacent first area 20.

Put another way, each first area 20 defines male member 30 along one (first) longitudinal edge and a female member 32 along an opposite (second) longitudinal edge. Likewise, each second area 22 defines a male member 30 along one (third) longitudinal edge and a female member 32 along an opposite (fourth) longitudinal edge. Thus, the male member 30 defined by the first longitudinal edge of the first area 20 is mated to the female member 32 defined by the fourth longitudinal edge of an adjacently positioned second area 22. Additionally, the male member 30 defined by the third longitudinal edge of the second area 22 is mated to the female member 32 defined by the second longitudinal edge of an adjacently positioned first area 20.

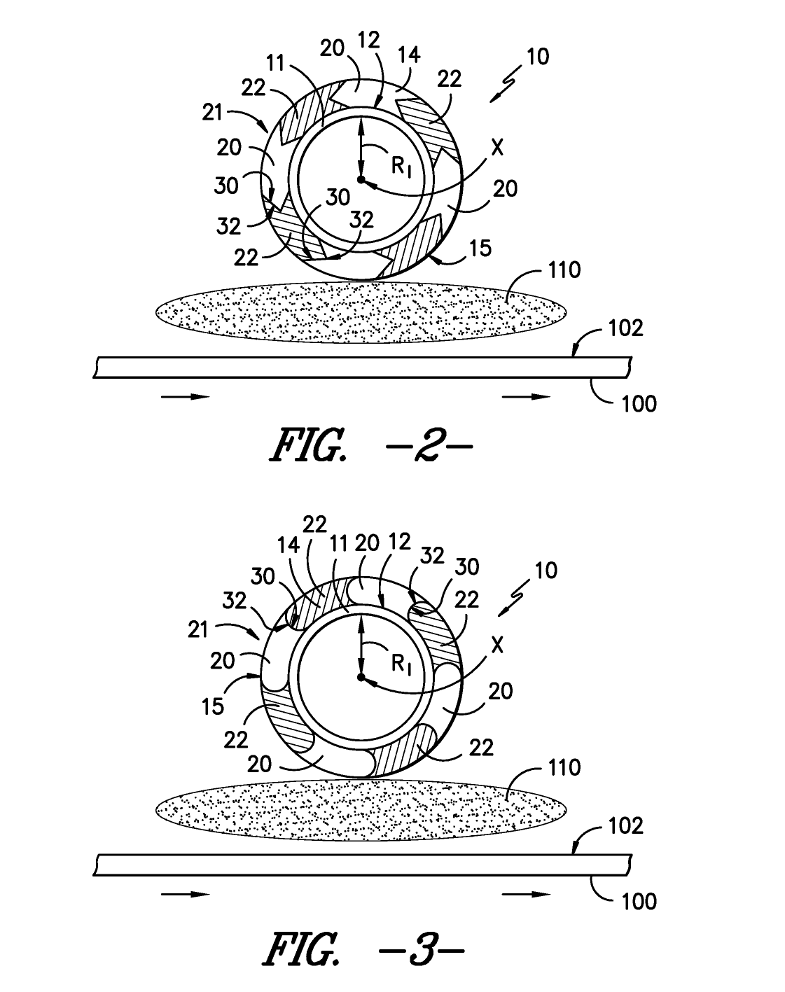

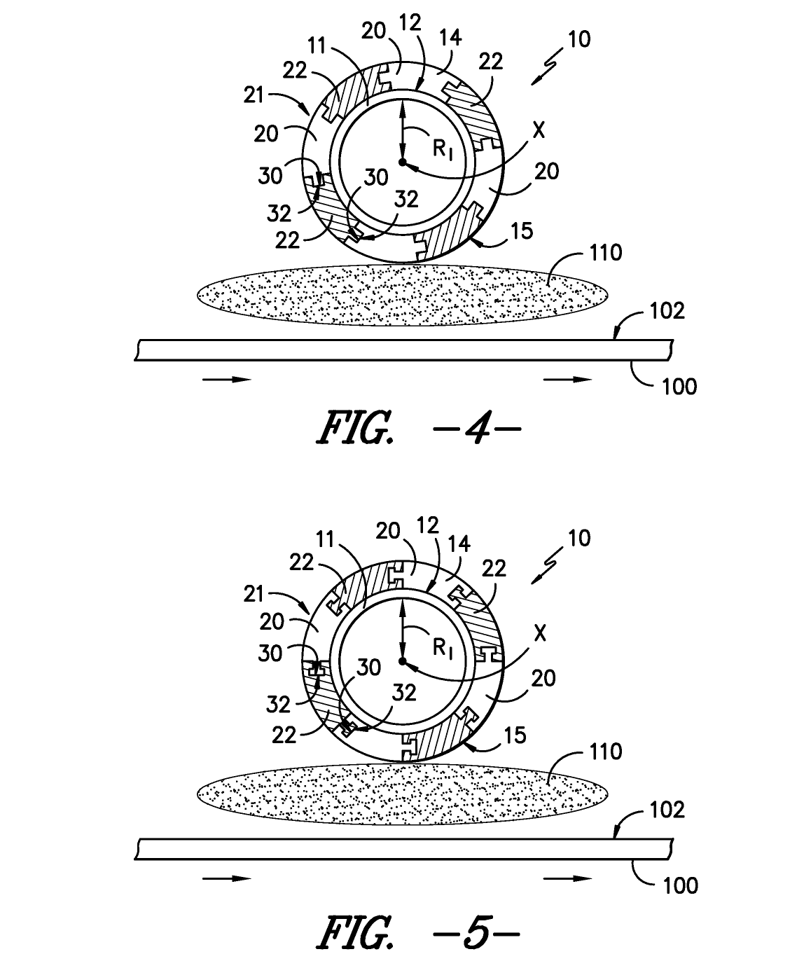

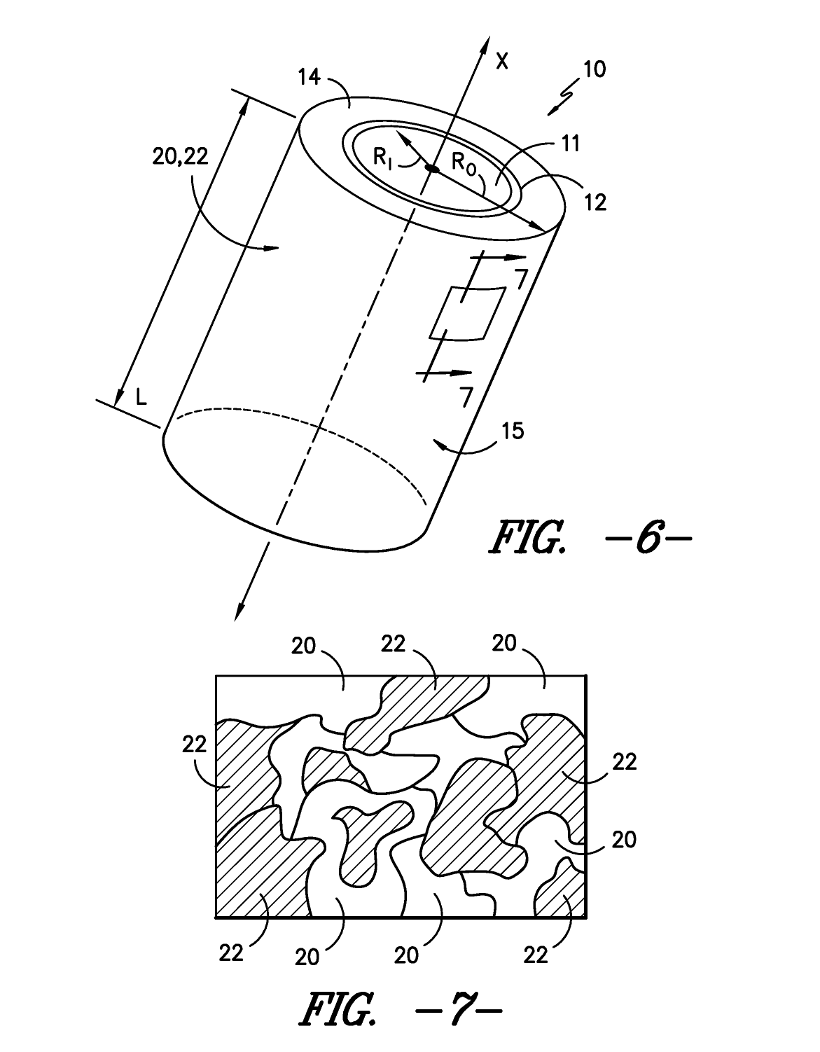

Each of FIGS. 2-5 shows one particular embodiment of the male members and their corresponding female members 32. For example, FIG. 2 shows a point-shaped male member 30 with a corresponding recess shaped female member 32. Alternatively, FIG. 3 shows a round-shaped male member 30 with a corresponding recess shaped female member 32. FIG. 4 shows a notch-shaped male member 30 with a corresponding recess shaped female member 32. Finally, FIG. 5 shows a T-shaped male member 30 with a corresponding recess shaped female member 32. However, the male members 30 and/or female members 32 can have any suitable shape. Such mating of the first areas 20 and the second areas 22 can not only keep the strips together, but can also ensure that a slit of other opening is not present between areas 20, 22 to allow the plasma 110 to reach and contact the tubular member 11 during sputtering.

Due to the particular configuration of alternating strips 21, each first area 20 and second area 22 can be formed (e.g., extruded, cast, machined, etc.) independently from the first compound and second compound, respectively. Then, the areas 20, 22 can be arranged around the tubular member 11 to form the sputtering material 14.

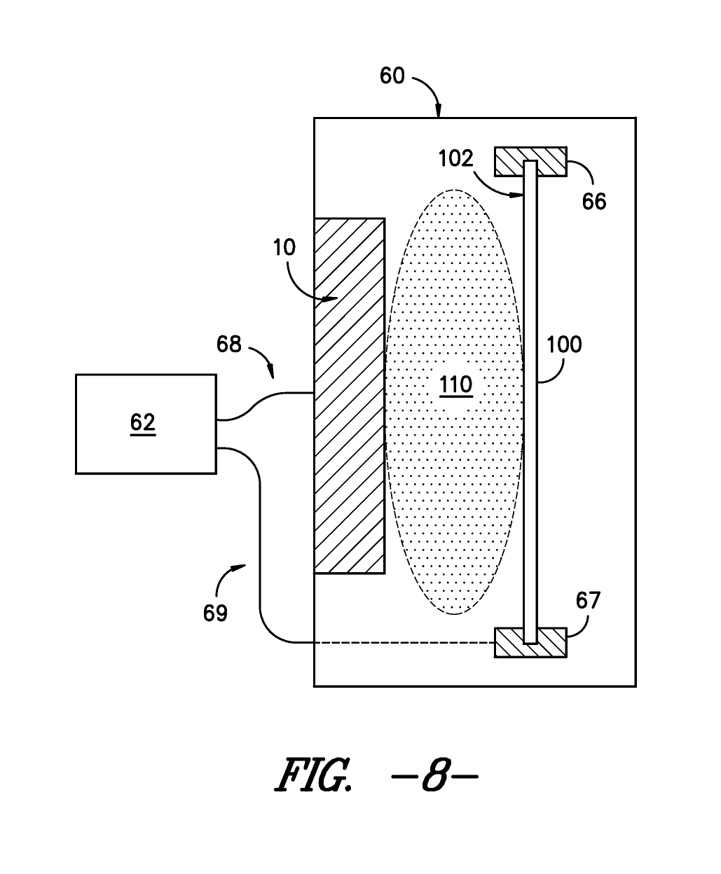

In the exemplary embodiment shown in FIGS. 6-7, the first area 20 and the second area 22 are randomly dispersed across the sputtering surface 15. Methods for forming this mixture can include melting two materials in an agitated liquid phase and then quenching the liquid very quickly to “freeze” in the mixture. In such a method, the quench time must be sufficiently short that the material which solidifies at a higher temperature does not aggregate before the lower temperature material can solidify, and conversely, the lower temperature material must not pool together before it can solidify. Alternatively, the materials can be fused together without completely melting them. In such a method, suitable embodiments can include warm pressing, cold pressing, and cold spray from powders of the starting materials, where the powder size dictates the domain size.

Although shown and described with two separate areas 20, 22, it should be understood that the cylindrical target 10 is not limited by any particular number of areas. For example, the sputtering surface 15 can include a plurality of third areas (not shown) that include a third compound that is different than both the first compound and the second compound. Additionally, the sputter surface 15 can include a plurality of fourth areas (not shown) that include a fourth compound that is different than all of the first compound, the second compound, and the third compound.

Referring to FIGS. 2-5, a thin film layer 102 is formed on a substrate 100 via sputtering deposition utilizing the cylindrical target 10. During deposition of the thin film layer 102, the cylindrical target 10 is rotated about its center axis (X) while the sputtering surface 15 contacts a plasma 110. The plasma 110 ejects atoms from the sputtering surface 15 of the source material 14. As individual substrates 100 are transported (e.g., conveyed, carried, etc.) across the plasma 110 at a substantially constant speed, the atoms ejected from the sputtering surface 15 are deposited onto the substrate 100 to form the thin film layer 102 thereon.

During the deposition process, the rotation rate of the cylindrical target 10 and the transport rate of the substrate 100 are selected to ensure that the thin film layer 102 is substantially homogeneous, even though the sputtering surface defines an inhomogeneous material. For example, the cylindrical target 10 rotates, in one embodiment, at a minimum speed according to the formula:

R_{d}/t<( ω̅*r)/L

where: ω̅ represents the angular velocity that the cylindrical target 10 is rotated about the center axis (X), r represents the outer radius (R_{O}) of the cylindrical target 10, t represents the monolayer thickness of the thin film layer formed during sputtering, L represents the greater of either the first characteristic length or the second characteristic length or less (e.g., the L represents the lesser of either the first characteristic length or the second characteristic length), and R_{d} represents the deposition rate of the atoms onto the substrate 100 (i.e., the rate of formation of the thin film layer 102). The deposition rate (R_{d}) is expressed in terms of thickness/time (e.g., nanometers/seconds).

The characteristic width (W) refers to the widths of each strip where the first material and second material can have different width to get the desired stoichiometry and account for differences in sputter rate. For instance, if it is desirable to deposit a thin film having a 2:1 ratio of materials A and B, respectively, then the characteristic width (e.g. length of the strips) of A will be twice that of B, if A and B have the same sputter rate. Alternatively, if it is desirable to deposit a thin film having a 1:1 ratio of materials C and D, but the sputter rate of C is 3 times than of D, then the characteristic width of D (e.g. width of the strips) will be 3 times that of C. Furthermore, in the case of materials with dissimilar sputter rates, the shape of the “keys” as described in FIGS. 2-5 need to be considered such that the stoichiometry of the sputtered material does not substantially change during the life of the target.

Thus, the cylindrical target 10 can be more uniformly sputtered during the deposition process and can lead to the formation of more uniform thin film layers (e.g., cadmium sulfide thin film layers, cadmium tin oxide layers, etc.), both on a single substrate and throughout the manufacturing process (i.e., from substrate to substrate).

In one particular embodiment, the angular velocity of the target can change during sputtering, as the outer radius decreases in size. For example, as the radius decreases, the angular velocity of the target can increase. However, the relationship between the radius and the angular velocity is not necessarily linear, in that the characteristic length (L) may also decrease as the radius decreases.

The cylindrical target 10 can be utilized with any suitable sputtering process and/or apparatus. Sputtering deposition generally involves ejecting material from the target, which is the material source, by contacting the target with a plasma. The ejected material can then be deposited onto the substrate to form the film. DC sputtering generally involves applying a voltage to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere), and can have a relatively low sputtering pressure (e.g., about 1 mTorr and about 20 mTorr).

FIG. 8 shows a general schematic as a cross-sectional view of an exemplary DC sputtering chamber 60 according to one embodiment. A DC power source 62 is configured to control and supply DC power to the chamber 60. As shown, the DC power source applies a voltage to the cylindrical target 10 (serving as a cathode) to create a voltage potential between the target 10 and an anode formed by the chamber wall, such that the substrate 100 is in between the cathode and anode. The substrate 100 (e.g., a glass substrate) is held between top support 66 and bottom support 67 and is connected to the power supply 62 via wires 68 and 69, respectively. Generally, the substrate 100 is positioned within the sputtering chamber 60 such that thin film layer 102 is formed on the substrate 100 faces the target 10.

A plasma field 110 is created once the sputtering atmosphere is ignited, and is sustained in response to the voltage potential between the target 10 and the chamber wall acting as an anode. The voltage potential causes the plasma ions within the plasma field 110 to accelerate toward the target 10, causing atoms from the sputtering surface 15 of the target 10 to be ejected toward the substrate 100. As such, the target 10 acts as the source material for the formation of the thin film layer 102 on the substrate 100. As stated, the target 10 can be a mixed metal target, such as elemental tin, cadmium, and/or zinc, or mixtures thereof. The sputtering atmosphere can contain oxygen gas, particularly when utilizing a metal target, oxygen particles of the plasma field 110 can react with the ejected target atoms to form the thin film layer 102 on the substrate 100.

During sputtering deposition, the cylindrical target 10 is rotated about its longitudinal axis as discussed above.

Although only a single DC power source 62 is shown, the voltage potential can be realized through the use of multiple power sources coupled together. Additionally, the exemplary sputtering chamber 60 is shown having a vertical orientation, although any other configuration can be utilized.

The presently provided methods and apparatus can be utilized in the formation of any film layer, particularly those suitable for inclusion in a photovoltaic thin film stack. For example, a transparent conductive oxide layer (e.g., formed from cadmium stannate), a resistive transparent buffer layer (e.g., formed from a zinc-tin oxide), and/or an n-type window layer formed from cadmium sulfide can be deposited using a cylindrical target 10 as described above. For example, the thin film layer(s) can be used during the formation of any cadmium telluride device that utilizes a cadmium telluride layer, such as in the cadmium telluride thin film photovoltaic device disclosed in U.S. Publication No. 2009/0194165 of Murphy, et al. titled “Ultra-high Current Density Cadmium Telluride Photovoltaic Modules.”

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method of forming a thin film layer on a substrate, the method comprising:
rotating a cylindrical target about a center axis, wherein the cylindrical target comprises a source material forming a sputtering surface about the cylindrical target, and wherein source material comprises a plurality of first areas and a plurality of second areas, each first area comprising a first compound and each second area comprising a second compound, the first compound being different than the second compound;
ejecting atoms from the sputtering surface with a plasma;
transporting a substrate across the plasma at a substantially consistent speed; and
depositing the atoms ejected from the sputtering surface onto the substrate to form a thin film layer.

2. The method as in claim 1, wherein the thin film layer comprises a deposited compound that includes both the first compound and the second compound.

3. The method as in claim 1, wherein the thin film layer is substantially homogeneous.

4. The method as in claim 1, wherein the cylindrical target is rotated about the center axis at an angular velocity so as to provide a predetermined deposition rate.

5. The method as in claim 1, wherein the cylindrical target is rotated about the center axis at an angular velocity, the atoms deposit onto the substrate to form the thin film layer having a monolayer thickness at a deposition rate, the cylindrical target defines a radius from the center axis to the sputtering surface, the first area defines a first characteristic length, and the second area defines a second characteristic length;
wherein the cylindrical target rotates at the angular velocity determined by the relationship of the angular velocity, the deposition rate, the radius, the monolayer thickness of the thin film layer, the first characteristic length, and/or the second characteristic length.

6. The method as in claim 5, wherein the angular velocity changes during sputtering.

7. The method as in claim 1, wherein the cylindrical target is rotated about the center axis at an angular velocity, the atoms deposit onto the substrate to form the thin film layer having a monolayer thickness at a deposition rate, the cylindrical target defines a radius from the center axis to the sputtering surface, the first area defines a first arc length, and the second area defines a second arc length;
wherein the cylindrical target rotates at a minimum speed according to the formula:
R_{d}/t<( ω̅*r)/L
where:
ω̅ represents the angular velocity that the cylindrical target is rotated about the center axis,
r represents the radius of the cylindrical target,
t represents the monolayer thickness of the thin film layer formed during sputtering,
L represents the greater of either the arc characteristic length or the second arc length, and
R_{d} represents the deposition rate.

8. The method as in claim 1, wherein the cylindrical target is rotated about the center axis at an angular velocity, the atoms deposit onto the substrate to form the thin film layer having a monolayer thickness at a deposition rate, the cylindrical target defines a radius from the center axis to the sputtering surface, the first area defines a first arc length, and the second area defines a second arc length;
wherein the cylindrical target rotates at a minimum speed according to the formula:
R_{d}/t<( ω̅*r)/L
where:
ω̅ represents the angular velocity that the cylindrical target is rotated about the center axis,
r represents the radius of the cylindrical target,
t represents the monolayer thickness of the thin film layer formed during sputtering,
L represents the lesser of either the first characteristic length or the second characteristic length, and
R_{d} represents the deposition rate.

9. The method as in claim 1, wherein the first characteristic length is equal to the second characteristic length.

10. The method as in claim 1, wherein the first compound and the second compound are not miscible materials.

11. The method as in claim 10, wherein the first compound comprises cadmium, and wherein the second compound comprises tin.

12. The method as in claim 11, wherein at least one of the first compounds or the second compound comprises oxygen.

13. The method as in claim 12, wherein the thin film layer comprises cadmium stannate.

14. The method as in claim 11, wherein the source material comprises cadmium and tin in a stoichiometric ratio between about 2 to 1 and about 10 to 1.

15. The method as in claim 11, wherein the plasma comprises oxygen.

16. The method as in claim 1, wherein the first area and the second area form alternating strips in the sputtering surface.

17. The method as in claim 16, wherein the alternating strips span from a first end of the cylindrical target to a second end of the cylindrical target.

18. The method as in claim 16, wherein the alternating strips are keyed together such that one first area is mechanically interlocked with an adjacent second area.

19. The method as in claim 18, wherein each first area defines a male member and a female member, and wherein each second area defines a substantially identical male member and a substantially identical female member.

20. The method as in claim 1, wherein the first area and the second area are randomly dispersed across the sputtering surface.
